(19) United States
(12) Patent Application Publication
(10) Pub. No.: US 2026/0066888 A1
(43) Pub. Date: Mar. 5, 2026

(54) ANALOG RADIO FREQUENCY PULSE GENERATORS WITH COMPENSATION

(71) Applicant: International Business Machines Corporation, Armonk, NY (US)

(72) Inventors: Daniil Frolov, New York, NY (US); Sudipto Chakraborty, Plano, TX (US); Subhajit Ray, New York, NY (US); Devin Underwood, Bronx, NY (US)

(21) Appl. No.: 18/818,993

(22) Filed: Aug. 29, 2024

(51) Int. Cl. H03K 5/14; H03D 7/00; H03K 5/00; H03L 7/099

(52) U.S. Cl. CPC H03K 5/14; H03D 7/00; H03L 7/099; H03K 2005/00078

(57) ABSTRACT

A device comprises a radio frequency signal generator which comprises a first signal path, a second signal path, a signal combiner, and a quadrature mixer. The first signal path is configured to generate an analog pulse. The second signal path is configured to generate a delayed analog pulse. The signal combiner is configured to combine the analog pulse and the delayed analog pulse to generate an analog compensation pulse. The quadrature mixer is configured to utilize the analog pulse and the analog compensation pulse to modulate quadrature local oscillator signals and generate a radio frequency control signal. The radio frequency control signal comprises a frequency that corresponds to a frequency of the quadrature local oscillator signals, and a pulse shape which comprises a shape of the analog pulse modified by a shape of the analog compensation pulse.

### BACKGROUND

This disclosure relates generally to radio frequency (RF) signal generators and, in particular, to techniques for generating RF control pulses for controlling quantum devices such as quantum bits (qubits) in a quantum computing system, etc. In quantum computing applications, RF signal generators (such as arbitrary waveform generators (AWGs)) are utilized to generate RF control pulses with desired frequencies and pulse shapes to control quantum devices (e.g., qubits) of a quantum processor. While general purpose RF AWGs can be utilized to generate control pulses for qubit control, such general-purpose RF AWGs typically consume a relatively high amount of power. Such high power consumption is the result of, e.g., operating multiple digital-to-analog converters to read digital data from a waveform memory and convert the digital data to continuous baseband signals that represent pulse envelopes which are that are used to generate RF control pulses, as well as compensation pulses, such as Derivative Removal by Adiabatic Gate (DRAG) pulses, which are utilized to modify the shapes of the RF control pulses that are applied to qubits to thereby improve the fidelity of quantum gate operations. Such high-power consumption is prohibitive for implementing such general-purpose RF AWGs in various applications such as cryogenic applications for superconducting quantum computing, where such high-power consumption increases the thermal load on a cryostat or dilution refrigerator.

### SUMMARY

Exemplary embodiments of the disclosure include analog RF signal generators and techniques for generating analog RF control pulses.

An exemplary embodiment includes a device which comprises a radio frequency signal generator, where the radio frequency signal generator comprises a first signal path, a second signal path, a signal combiner, and a quadrature mixer. The first signal path is configured to generate an analog pulse. The second signal path is configured to generate a delayed analog pulse. The signal combiner is configured to combine the analog pulse and the delayed analog pulse to generate an analog compensation pulse. The quadrature mixer is configured to utilize the analog pulse and the analog compensation pulse to modulate quadrature local oscillator signals and generate a radio frequency control signal. The radio frequency control signal comprises a frequency which corresponds to a frequency of the quadrature local oscillator signals, and a pulse shape which comprises a shape of the analog pulse modified by a shape of the analog compensation pulse.

Another exemplary embodiment includes a system which comprises a quantum processor, and a radio frequency signal generator system. The quantum processor comprises at least one quantum bit. The radio frequency signal generator system comprises at least one radio frequency signal generator channel that is configured to generate a radio frequency control signal to control the at least one quantum bit. The at least one radio frequency signal generator channel comprises a first signal path, a second signal path, a signal combiner, and a quadrature mixer. The first signal path is configured to generate an analog pulse. The second signal path is configured to generate a delayed analog pulse. The signal combiner is configured to combine the analog pulse and the delayed analog pulse to generate an analog compensation pulse. The quadrature mixer is configured to utilize the analog pulse and the analog compensation pulse to modulate quadrature local oscillator signals and generate the radio frequency control signal to control the at least one quantum bit. The radio frequency control signal comprises a frequency which corresponds to a frequency of the quadrature local oscillator signals, and a pulse shape which comprises a shape of the analog pulse modified by a shape of the analog compensation pulse.

Another exemplary embodiment includes a system which comprises a radio frequency signal generator, and a control system. The radio frequency signal generator comprises analog circuitry. The analog circuitry is configured to: generate an analog pulse; generate a delayed analog pulse; combine the analog pulse and the delayed analog pulse to generate an analog compensation pulse; and amplitude modulate quadrature local oscillator signals using the analog pulse and the analog compensation pulse to generate a radio frequency control signal. The radio frequency control signal comprises a frequency which corresponds to a frequency of the quadrature local oscillator signals, and a pulse shape which comprises a shape of the analog pulse modified by a shape of the analog compensation pulse. The control system is configured to generate digital control signals to control the analog circuitry to adjust parameters of the radio frequency control signal by controllably adjusting: a pulse width of the analog pulse; a time delay between the analog pulse and the delayed analog pulse; a phase-shift of the quadrature local oscillator signals; and an amplitude of the radio frequency control signal.

Other embodiments will be described in the following detailed description of exemplary embodiments, which is to be read in conjunction with the accompanying figures.

### BRIEF DESCRIPTION OF THE DRAWINGS

FIG. 1 schematically illustrates an analog RF pulse generator, according to an exemplary embodiment of the disclosure.

FIG. 2 schematically illustrates an analog RF pulse generator, according to another exemplary embodiment of the disclosure.

FIG. 3 schematically illustrates an analog RF pulse generator, according to another exemplary embodiment of the disclosure.

FIG. 4A depicts a frequency-domain graph of simulated RF output signals that can be generated using an analog RF pulse generator, according to an exemplary embodiment of the disclosure.

FIG. 4B depicts a time-domain graph of simulated DRAG pulses that are generated by computing a derivative of a Gaussian pulse and scaling the computed derivative with different scaling parameters, according to an exemplary embodiment of the disclosure.

FIG. 4C depicts a time-domain graph of simulated DRAG pulses that are generated by varying a time delay between two Gaussian pulses which are combined to generate the DRAG pulses, according to an exemplary embodiment of the disclosure.

FIG. 5 schematically illustrates an analog RF pulse generator, according to another exemplary embodiment of the disclosure.

FIG. 6 schematically illustrates a quantum computing system which a implements multi-channel analog RF pulse generator to generate RF pulses for controlling qubits of a quantum processor, according to an exemplary embodiment of the disclosure.

FIG. 7 schematically illustrates a quantum computing system, according to another exemplary embodiment of the disclosure.

FIG. 8 schematically illustrates an exemplary computing environment which is configured to execute program instructions for performing quantum computing operations and controlling RF pulse generators, according to an exemplary embodiment of the disclosure.

### DETAILED DESCRIPTION

Exemplary embodiments of the disclosure will now be described in further detail with regard to analog RF pulse generators and techniques for generating analog RF control pulses for, e.g., quantum computing systems. For example, exemplary embodiments of the disclosure include analog RF pulse generators and techniques for generating analog RF control pulses to control quantum devices such as qubits, wherein the analog RF control pulses are generated using compensation pulses (or auxiliary pulses) to further shape the analog RF control pulses and thereby improve the fidelity of qubit gate operations.

In some embodiments, the exemplary analog RF pulse generators and techniques described herein are configured to generate shaped RF control pulses that are calibrated to drive f₀₁ transitions of qubits (e.g., transitions between a ground state |0 [symbol] and a first excited state |1 [symbol] , or a superposition state thereof), while suppressing higher qubit state transitions such as f₁₂ (e.g., transitions between the first excited state |1 [symbol] and second excited state |2 [symbol] , and higher transitions. Essentially, such pulse shaping techniques serve to suppress/reduce the transients associated with turning the control pulses on and off. Moreover, the exemplary analog RF pulse generators and techniques described herein are configured to implement pulse shaping techniques by generating and utilizing analog compensation pulses, such as analog DRAG pulses, in conjunction with shaped pulses (such as Gaussian pulses, cosine pulses, or hyperbolic secant pulses) to further suppress unwanted state transitions, while maintaining a same pulse envelope area (or integral of pulse envelope).

As is known in the art, DRAG compensation is a technique that can be utilized in quantum computing to improve the fidelity of qubit operations. DRAG is utilized to reduce errors that are caused by unwanted qubit state transition to higher energy levels, e.g., transitions from the first excited state |1 [symbol] to the second excited state |2 [symbol] . In general, DRAG compensation involves modifying a shaped pulse, e.g., Gaussian pulse, by adding a derivative component to the shaped pulse, e.g., adding a derivative of the Gaussian pulse to the Gaussian pulse, wherein the derivative component further helps to shape the Gaussian pulses in manner that serves to minimize a spectral overlap with higher energy states. In this regard, DRAG compensation can be utilized to increase the fidelity of qubit gate operations.

An exemplary embodiment includes a device which comprises a radio frequency signal generator, where the radio frequency signal generator comprises a first signal path, a second signal path, a signal combiner, and a quadrature mixer. The first signal path is configured to generate an analog pulse. The second signal path is configured to generate a delayed analog pulse. The signal combiner is configured to combine the analog pulse and the delayed analog pulse to generate an analog compensation pulse. The quadrature mixer is configured to utilize the analog pulse and the analog compensation pulse to modulate quadrature local oscillator signals and generate a radio frequency control signal. The radio frequency control signal comprises a frequency which corresponds to a frequency of the quadrature local oscillator signals, and a pulse shape which comprises a shape of the analog pulse modified by a shape of the analog compensation pulse.

Another exemplary embodiment includes a system which comprises a quantum processor, and a radio frequency signal generator system. The quantum processor comprises at least one quantum bit. The radio frequency signal generator system comprises at least one radio frequency signal generator channel that is configured to generate a radio frequency control signal to control the at least one quantum bit. The at least one radio frequency signal generator channel comprises a first signal path, a second signal path, a signal combiner, and a quadrature mixer. The first signal path is configured to generate an analog pulse. The second signal path is configured to generate a delayed analog pulse. The signal combiner is configured to combine the analog pulse and the delayed analog pulse to generate an analog compensation pulse. The quadrature mixer is configured to utilize the analog pulse and the analog compensation pulse to modulate quadrature local oscillator signals and generate the radio frequency control signal to control the at least one quantum bit. The radio frequency control signal comprises a frequency which corresponds to a frequency of the quadrature local oscillator signals, and a pulse shape which comprises a shape of the analog pulse modified by a shape of the analog compensation pulse.

In another exemplary embodiment, which may be combined with one or more of the embodiments of the preceding paragraphs, the analog pulse comprises a Gaussian pulse, the analog compensation pulse comprises a DRAG pulse, the analog compensation pulse comprises a pulse shape that corresponds to a derivative of the Gaussian pulse, and a magnitude of the derivative corresponds to an amount of time delay between the analog pulse and the delayed analog pulse.

In another exemplary embodiment, which may be combined with one or more of the embodiments of the preceding paragraphs, the first signal path comprises an analog pulse generator circuit which is configured to generate the analog pulse in response to a control trigger pulse, and the analog pulse generator circuit is responsive to a first digital control signal to generate the analog pulse having a pulse width which is specified by the first digital control signal.

In another exemplary embodiment, which may be combined with one or more of the embodiments of the preceding paragraphs, the analog pulse generator circuit comprises a ramp signal generator, and an analog pulse generator. The ramp signal generator is configured to generate a linear ramp signal in response to the control trigger pulse, the linear ramp signal having a slope which is specified by the first digital control signal. The analog pulse generator is configured to convert the linear ramp signal to an analog pulse having a Gaussian shape and a pulse width that is based on the slope of the linear ramp signal.

In another exemplary embodiment, which may be combined with one or more of the embodiments of the preceding paragraphs, the second signal path comprises a delay circuit which is configured to receive the analog pulse generated by the analog pulse generator circuit, and apply a time delay to the analog pulse to generate the delayed analog pulse. The delay circuit is responsive to a second control signal which specifies an amount of time delay to apply to the analog pulse.

In another exemplary embodiment, which may be combined with one or more of the embodiments of the preceding paragraphs, the first signal path comprises a first analog pulse generator circuit which is configured to generate a first analog pulse in response to a control trigger pulse, and which is responsive to a first digital control signal to generate the first analog pulse having a pulse width that is specified by the first digital control signal. The second signal path comprises a delay circuit, and a second analog pulse generator circuit. The delay circuit is configured to receive the control trigger pulse concurrently with the first analog pulse generator circuit, and apply a time delay to the control trigger pulse to generate a delayed control trigger pulse. The second analog pulse generator circuit is configured to generate a second analog pulse in response to the delayed control trigger pulse, and is responsive to the first digital control signal to generate the second analog pulse having as same pulse width as the first analog pulse, which is specified by the first digital control signal. The signal combiner generates the analog compensation pulse by combing the first analog pulse and the second analog pulse, the second analog pulse being time-delayed relative to the first analog pulse based on the time delay applied to the control trigger pulse by the delay circuit.

In another exemplary embodiment, which may be combined with one or more of the embodiments of the preceding paragraphs, the radio frequency signal generator comprises a quadrature local oscillator generator which is configured to generate the quadrature local oscillator signals including an in-phase local oscillator signal and a quadrature-phase local oscillator signal. The quadrature local oscillator generator is responsive to a third digital control signal to cause the quadrature local oscillator signals to have a phase shift which is specified by the third digital control signal.

In another exemplary embodiment, which may be combined with one or more of the embodiments of the preceding paragraphs, the quadrature mixer comprises a first mixer and a second mixer. The first mixer comprises a first input port to receive the analog pulse, a second input port to receive the in-phase local oscillator signal, and an output port to output a first modulated signal comprising the in-phase local oscillator signal amplitude modulated by the analog pulse. The second mixer comprises a first input port to receive the analog compensation pulse, a second input port to receive the quadrature-phase local oscillator signal, and an output port to output a second modulated signal comprising the quadrature-phase local oscillator signal amplitude modulated by the analog compensation pulse. The quadrature mixer is configured to combine the first modulated signal and the second modulated signal to generate the radio frequency control signal.

In another exemplary embodiment, which may be combined with one or more of the embodiments of the preceding paragraphs, the quadrature local oscillator generator comprises: a phase-lock loop circuit and a quadrature frequency divider circuit. The phase-lock loop is configured to generate a local oscillator signal having a frequency which is double the frequency of the quadrature local oscillator signals. The phase-lock loop is responsive to the third digital control signal to apply the phase shift to the local oscillator signal that is output from the phase-lock loop circuit. The quadrature frequency divider circuit is configured to divide the local oscillator signal that is output from the phase-lock loop circuit to generate the in-phase local oscillator signal and the quadrature-phase local oscillator signal.

In another exemplary embodiment, which may be combined with one or more of the embodiments of the preceding paragraphs, the radio frequency signal generator further comprises a gain adjust circuit coupled to an output of the quadrature mixer. The gain adjust circuit is configured to adjust an amplitude of the radio frequency control signal in response to a fourth digital control signal applied to the gain adjust circuit.

Another exemplary embodiment includes a system which comprises a radio frequency signal generator, and a control system. The radio frequency signal generator comprises analog circuitry. The analog circuitry is configured to: generate an analog pulse; generate a delayed analog pulse; combine the analog pulse and the delayed analog pulse to generate an analog compensation pulse; and amplitude modulate quadrature local oscillator signals using the analog pulse and the analog compensation pulse to generate a radio frequency control signal. The radio frequency control signal comprises a frequency which corresponds to a frequency of the quadrature local oscillator signals, and a pulse shape which comprises a shape of the analog pulse modified by a shape of the analog compensation pulse. The control system is configured to generate digital control signals to control the analog circuitry to adjust parameters of the radio frequency control signal by controllably adjusting: a pulse width of the analog pulse; a time delay between the analog pulse and the delayed analog pulse; a phase-shift of the quadrature local oscillator signals; and an amplitude of the radio frequency control signal.

In another exemplary embodiment, which may be combined with one or more of the embodiments of the preceding paragraphs, the analog pulse comprises a Gaussian pulse, the analog compensation pulse comprises a DRAG pulse, the analog compensation pulse comprises a pulse shape that corresponds to a derivative of the Gaussian pulse, and a magnitude of the derivative corresponds to an amount of time delay between the analog pulse and the delayed analog pulse.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise discrete circuit elements (e.g., transistors, inverters, etc.), superconducting elements such as superconducting quantum bits, programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

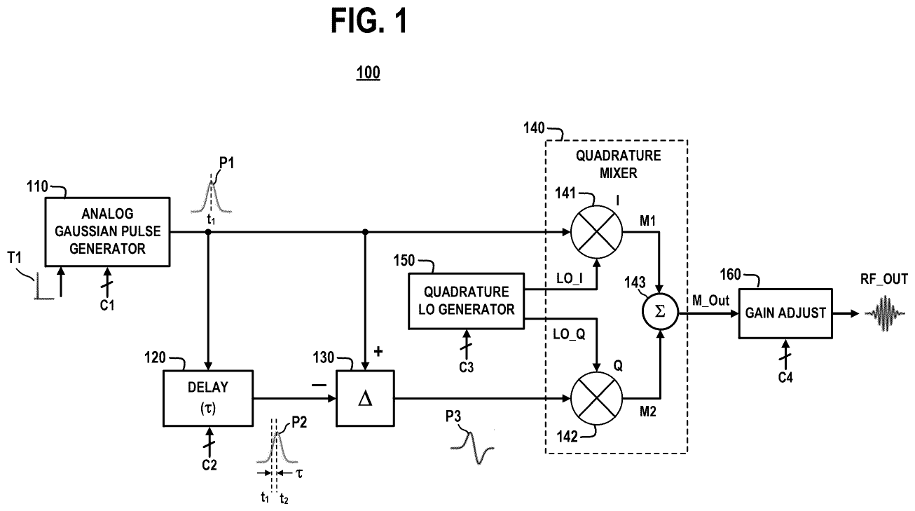

FIG. 1 schematically illustrates an analog RF pulse generator, according to an exemplary embodiment of the disclosure. In particular, FIG. 1 schematically illustrates an analog RF pulse generator 100 that is configured to generate an RF output signal, RF_OUT, which comprises a Gaussian-shaped RF control pulse with DRAG compensation, according to an exemplary embodiment of the disclosure. The analog RF pulse generator 100 comprises an analog Gaussian pulse generator 110, a delay circuit 120, a signal combiner 130, a quadrature mixer 140, a quadrature local oscillator (LO) generator 150, and a gain adjust circuit 160. The quadrature mixer 140 comprises a first mixer 141 (or I-mixer), a second mixer 142 (or Q-mixer), and a signal combiner 143. The quadrature LO generator 150 is configured to generate quadrature LO signals including an in-phase LO signal (LO_I) and a quadrature-phase LO signal (LO_Q), which are utilized by the quadrature mixer 140 to perform I/Q modulation and upconversion operations, as discussed in further detail below.

The analog Gaussian pulse generator 110 comprises an output port that is coupled to (i) an input port of the delay circuit 120, (ii) an intermediate frequency (IF) input port of the first mixer 141, and to (iii) a first input port (e.g., positive (+) input port) of the signal combiner 130. An output port of the delay circuit 120 is coupled to second input port (e.g., negative (−) input port) of the signal combiner 130. An output port of the signal combiner 130 is coupled to an intermediate frequency (IF) input port of the second mixer 142. The first mixer 141 comprises an LO input port which receives the LO_I signal. The second mixer 142 comprises LO input port which receives the LO_Q signal. A first input port of the signal combiner 143 is coupled to an output port (RF port) of the first mixer 141. A second input port of the signal combiner 143 is coupled to an RF port of the second mixer 142. An output port of the signal combiner 143 is coupled to an input port of the gain adjust circuit 160.

The analog Gaussian pulse generator 110 comprises analog circuitry which is configured to generate a Gaussian pulse, denoted P1. In some embodiments, the analog Gaussian pulse generator 110 generates a Gaussian pulse P1 in response to a trigger signal T1 that is applied to a control input of the analog Gaussian pulse generator 110. The analog Gaussian pulse generator 110 can be implemented using known circuit architectures and analog pulse generation techniques to generate Gaussian pulses. In some embodiments, the analog Gaussian pulse generator 110 is configured to generate and output the Gaussian pulse P1, wherein the Gaussian pulse can be a current pulse or a voltage pulse, generally denoted as g(t). In some embodiments, the analog Gaussian pulse generator 110 is programmatically controlled by a first control signal C1 to control a width of the Gaussian pulse P1, which, in turn, defines a width of the RF output signal RF_OUT.

The delay circuit 120 is configured to receive the Gaussian pulse P1 and apply a specified time delay (τ) (or propagation delay) and output a second Gaussian pulse P2 which comprises a time-delayed version of the input Gaussian pulse P1. In some embodiments, second Gaussian pulse is a current pulse or voltage pulse, generally denoted as g(t+τ). The delay circuit 120 can be implemented using known circuit architectures and analog signal delay techniques to generate the time-delayed Gaussian pulse P2. In some embodiments, the delay circuit 120 is programmatically controlled by a second control signal C2 to adjust the amount of time delay (τ) applied to the first Gaussian pulse P1. The time delay (τ) between the first and second Gaussian pulses P1 and P2 defines a DRAG coefficient (e.g., amplitude) of a DRAG pulse P3 that is generated by the signal combiner 130.

The signal combiner 130 is configured to combine the first and second Gaussian pulses P1 and P2 to generate the DRAG pulse P3. More specifically, in some embodiments, the signal combiner 130 generates the DRAG pulse P3 as a difference between the first and second Gaussian pulses P1 and P2, e.g., P1-P2, or g(t)−g(t+τ). As noted above, a DRAG pulse can be computed by taking a derivative of the Gaussian pulse P1. For example, a DRAG pulse can be generated by computing:

$$β \cdot \frac{dg ( t )}{dt} ,$$

where β denotes a scale factor that is applied to the derivative

$$\frac{dg ( t )}{dt}$$

of a Gaussian pulse g(t).

In this exemplary analog RF pulse generator configuration of FIG. 1, the DRAG pulse P3 is computed by taking the difference of first and second Gaussian pulses P1 and P2, e.g., g(t)−g(t+τ), where the difference is proportional to the derivative of the Gaussian pulse P1. In other words, the difference of first and second Gaussian pulses P1 and P2 is equivalent the derivative of the Gaussian pulse P1. Moreover, the amount of delay τ corresponds to the scaling value β. For example, increasing the delay τ increases the amplitude (scaling value β) of the DRAG pulse P3, while decreasing the delay τ decreases the amplitude (scaling value β) of the DRAG pulse P3.

As noted above, the quadrature LO generator 150 is configured to generate the quadrature LO signals LO_I and LO_Q, which are applied to the LO ports of the first and second mixers 141 and 142 respectively, to perform I/Q modulation and upconversion operations. As is known in the art, a quadrature signal comprises an in-phase (I) signal component, and a quadrature-phase (Q) signal component. A pair of signals that are in quadrature have the same frequency, but differ in phase by 90 degrees. For example, by convention, the LO_I signal is a cosine waveform, and the LO_Q signal component is a sine waveform, wherein the LO_I and LO_Q signals have the same LO frequency. For example, the LO frequency corresponds to a transition frequency f₀₁ of a qubit which is driven by the RF output signal RF_OUT that is generated by the analog RF pulse generator 100.

The quadrature LO generator 150 can be implemented using known circuit architectures and quadrature LO signal generation techniques to generate the quadrature LO signals LO_I and LO_Q for the quadrature mixer 140. In some embodiments, quadrature LO generator 150 is programmatically controlled by a third control signal C3 to modulate the phases of the quadrature LO signals LO_I and LO_Q. The phase modulation of the quadrature LO signals LO_I and LO_Q enables phase adjustment of a modulated RF signal that is generated and output from the quadrature mixer 140.

The quadrature mixer 140 is configured to perform I/Q amplitude modulation in which the Gaussian pulse P1 and the DRAG pulse P3 serve as modulating signals that modulate the respective signals LO_I and LO_Q. In particular, in the exemplary configuration of FIG. 1, the first (I) mixer 141 performs a mixing operation in which the Gaussian pulse P1 amplitude modulates the LO_I signal to generate a first modulated signal M1=g(t)·cos (wt). Similarly, the second (Q) mixer 142 performs a mixing operation in which the DRAG pulse P3 amplitude modulates the LO_Q signal to generate a second modulated signal M2=−sin (wt)·(g(t)−g(t+τ)). The signal combiner 143 combines (e.g., adds) the first and second modulated signals M1 and M2 to generate a modulated output signal M_OUT=g(t)·cos (wt)−sin (wt)·(g(t)−g(t+τ)).

The gain adjust circuit 160 is configured to receive the modulated output signal M_OUT and adjust the amplitude of the modulated output signal M_OUT to generate and output the RF output signal RF_OUT to drive a device (e.g., qubit) that is coupled to an output of the analog RF pulse generator 100. The gain adjust circuit 160 can be implemented using known analog signal amplifier/attenuator circuit architectures and analog signal amplification/attenuation techniques, which are suitable for the given application to generate the RF output signal RF_OUT. In some embodiments, the modulated output signal M_OUT is a current signal or voltage signal, and the gain adjust circuit 160 generates the RF output signal RF_OUT as a voltage signal. In some embodiments, the gain adjust circuit 160 is programmatically controlled by a fourth control signal C4 to adjust the amplitude of the RF output signal RF_OUT.

In an exemplary embodiment, the RF output signal RF_OUT comprises a Rabi pulse that is configured to drive and manipulate a qubit (e.g., control qubit state, perform a gate, and create a superposition state, etc.). A Rabi pulse is configured to expose a qubit to periodic electric or magnetic fields during a specific time interval to induce Rabi oscillations, as desired, to thereby manipulate the qubit to perform a single-qubit gate operation or otherwise modify the computational state of the qubit as needed when executing a quantum algorithm (e.g., place the qubit into a ground state 10), a first excited state |1), or a superposition state, etc.

Indeed, as is known in the art, the state of a qubit can be changed by applying a microwave control signal (e.g., RF control pulse) with a frequency (e.g., LO frequency) equal to a transition frequency (denoted f₀₁) of the qubit, wherein the transition frequency f₀₁ corresponds to an energy difference between the ground state |0 [symbol] and the first excited state |1 [symbol] of the qubit. In addition, the state of a qubit can be changed by rotating the state (axis of rotation) about a given axis of the Bloch sphere (e.g., X-axis, Y-axis, or any axis in the X-Y plane) and by a given amount (angle) of rotation by controlling a phase of the RF control pulse, and an amplitude and duration of the RF control pulse.

In this regard, as noted above, the duration of the RF control pulse is based at least in part on a pulse width of the Gaussian pulse P1 which is generated by the analog Gaussian pulse generator 110, wherein the first control signal C1 is used to set the pulse width of the Gaussian pulse P1 (and thus the duration of the RF control pulse). In addition, the phase of the RF signal component of the RF control pulse is based at least in part on the phase of the LO signals LO_I and LO_Q, wherein the third control signal C3 is used to modulate the phase of the LO signals LO_I and LO_Q, and thereby set the phase of the RF control pulse. The frequency of the RF signal component of the RF control pulse corresponds to the LO frequency, and the LO frequency is tuned by the quadrature LO generator 150 to, e.g., match the LO frequency to a transition frequency f₀₁ of a qubit. Moreover, the amplitude of the RF control pulse is based on the gain setting of the gain adjust circuit 160, wherein the fourth control signal C4 is used to set the amplitude of the RF control pulse. In addition, as noted above, the amount of DRAG compensation that is applied to the RF control pulse is based on the amount of time delay (τ) applied by the delay circuit 120, wherein second control signal C2 is utilized to set the desired time delay (τ).

It is to be appreciated that the exemplary analog RF pulse generator 100 of FIG. 1 and other embodiments of analog RF pulse generators as discussed herein provide scalable RF signal generator architectures which operate a low-powers enable integration of the analog RF pulse generators within cryogenic cooling chambers (e.g., cryostats, dilution refrigerator), and which provide sufficient functionality for generating RF control pulses for precise control of qubits. Indeed, as noted above, an analog RF pulse generator is configured to generate Gaussian control pulses with varying width and amplitude, as well as generate DRAG pulse to provide DRAG compensation.

In particular, the exemplary analog RF pulse generators discussed herein provide low-power architectures in which power is significantly reduced as compared to AWG systems which require significant digital overhead to generate RF control pulses. For example, some AWG systems utilize two high-speed digital-to-analog converters (DAC) (e.g., one (1) Giga samples per second) to generate I and Q baseband signals, wherein the I baseband signal comprises a Gaussian pulse and the Q baseband signal comprises a DRAG pulse. By way of specific example, a general-purpose AWG can be configured to access and process a large number of bits per cycles from a waveform memory (e.g., 16 samples*10 bits*2 DACs=320 bits per processor cycle), and compute phase coefficients. Such digital overhead requires relatively high-power consumption.

In contrast, as explained above, the exemplary analog RF pulse generator 100 of FIG. 1 is configured to generate a Gaussian-shaped RF control pulse with DRAG compensation using four (4) words per processor cycle (e.g., four digital control signals C1, C2, C3, and C4) to define the width, phase, amplitude, and DRAG parameters of a RF control pulse. Assuming that each digital control signal C1, C2, C3, and C4 has a 10-bit resolution, the exemplary analog RF pulse generator 100 would use a total number or 40 bits per processor cycle (as compared to 320 bits per cycle of the AWG system) to generate an RF control pulse with the defined width, phase, amplitude, and DRAG parameters, which amount to 88% less digital data than is needed by the AWG system to generate a RF control pulse. In addition, the exemplary analog RF pulse generator 100 does not implement DACs to generate the baseband signals, and utilized the quadrature LO generate to track and modulate the phase via the third control signal C3. In this regard, reducing the digital overhead results in reduced power consumption.

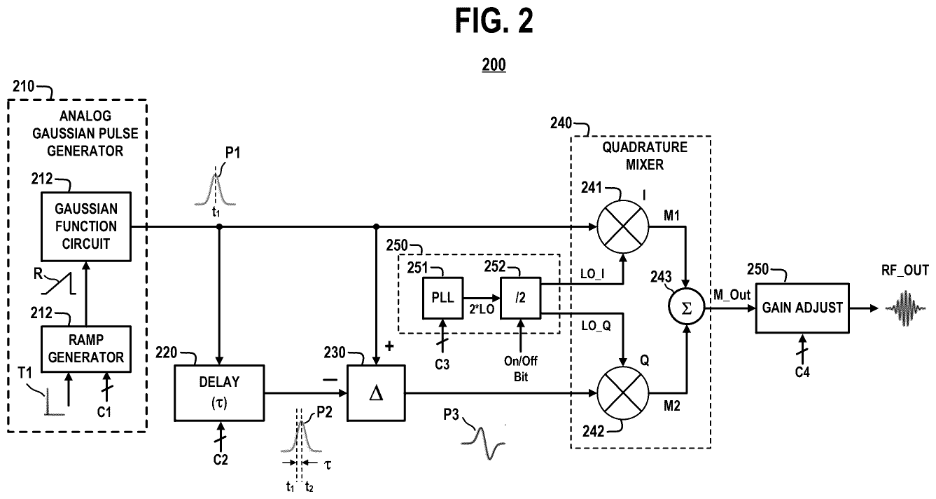

FIG. 2 schematically illustrates an analog RF pulse generator, according to another exemplary embodiment of the disclosure. In particular, FIG. 2 schematically illustrates an analog RF pulse generator 200 that is configured to generate an RF output signal, RF_OUT, which comprises a Gaussian-shaped RF control pulse with DRAG compensation, according to another exemplary embodiment of the disclosure. The analog RF pulse generator 200 comprises an analog Gaussian pulse generator 210, a delay circuit 220, a signal combiner 230, a quadrature mixer 240, a quadrature local oscillator (LO) generator 250, and a gain adjust circuit 260. The quadrature mixer 240 comprises a first mixer 241 (or I-mixer), a second mixer 242 (or Q-mixer), and a signal combiner 243.

In some embodiments, the delay circuit 220, the signal combiner 230, the quadrature mixer 240, and the gain adjust circuit 260 implement the same or similar circuit architectures and modes of operation as the corresponding circuit components of the analog RF pulse generator 100 of FIG. 1 as discussed above, the details of which need not be repeated. On the other hand, FIG. 2 schematically illustrate exemplary embodiments for implementing the analog Gaussian pulse generator 210, and the quadrature LO generator 250. In particular, the analog Gaussian pulse generator 210 comprises a ramp signal generator 211 and a Gaussian function circuit 212. The quadrature LO generator 250 comprises a phase-locked loop (PLL) circuit 252, and a quadrature frequency divider 252.

The analog Gaussian pulse generator 210 is configured to generate a Gaussian pulse P1 using a linear ramp signal R. In particular, the ramp signal generator 211 is configured to generate a linear ramp signal R, and the Gaussian function circuit 212 is configured to generate a Gaussian pulse P1 in response to the linear ramp signal R applied to an input port thereof. In some embodiments, the linear ramp signal comprises a voltage signal that starts at normalized voltage level of −1 and ramps up to a normalized voltage level of +1, with a given slope that is programmatically adjusted by the first control signal C1. The ramp signal generator 211 can be implemented using known circuit architectures to generate a ramp voltage signal, wherein the slope of the linear ramp signal R is adjusted to control a pulse width of the Gaussian pulse P1 that is generated and output from the Gaussian function circuit.

The Gaussian function circuit 212 comprises any suitable circuit architecture that is configured to generate a Gaussian pulse P1 (e.g., current pulse) in response to the linear ramp signal R, wherein the pulse width of the Gaussian pulse P1 is adjusted by changing the slope of the linear ramp signal R. For example, the slope of the linear ramp signal R can be decreased to increase the pulse width of the Gaussian pulse P1, while the slope of the linear ramp signal R can be increased to decrease the pulse width of the Gaussian pulse P1.

The quadrature LO generator 250 is configured to generate quadrature LO signals LO_I and LO_Q, which are utilized by the quadrature mixer 240 to perform I/Q modulation and upconversion operations, as discussed above. In some embodiments, the PLL circuit 251 is configured to generate an LO signal which is 2× the target LO frequency (e.g., 2× the transition frequency f₀₁ of a qubit that is driven by the RF_OUT signal generated by the analog RF pulse generator 200). For example, assuming the transition frequency f₀₁ of the qubit is 5.0 GHz, the PLL circuit 251 is configured to generate an LO signal with a frequency of 10.0 GHz. The quadrature frequency divider 252 is configured to divide the LO signal, which is generated and output from the PLL circuit 251, into quadrature LO signals LO_I and LO_Q, each having a frequency which is one-half the frequency (e.g., 5.0 GHz) of the LO signal that is output from the PLL circuit 251.

In some embodiments, the PLL circuit 251 comprise a PLL circuit architecture which is configured to synthesize a LO signal and modulate a phase (e.g., shift the phase) of the LO signal which is output from the PLL circuit 251. The implementation of the PLL circuit 251 allows the LO signal with the proper phase to be synthesized locally for better control. Moreover, in some embodiments, the quadrature frequency divider 252 comprises a digital circuit architecture which is configured to be turned On and Off by a single control bit applied thereto. With the single bit control, the quadrature frequency divider 252 can be quicky shut Off and On to stop and start the dividing operation, without shutting of the PLL circuit 251.

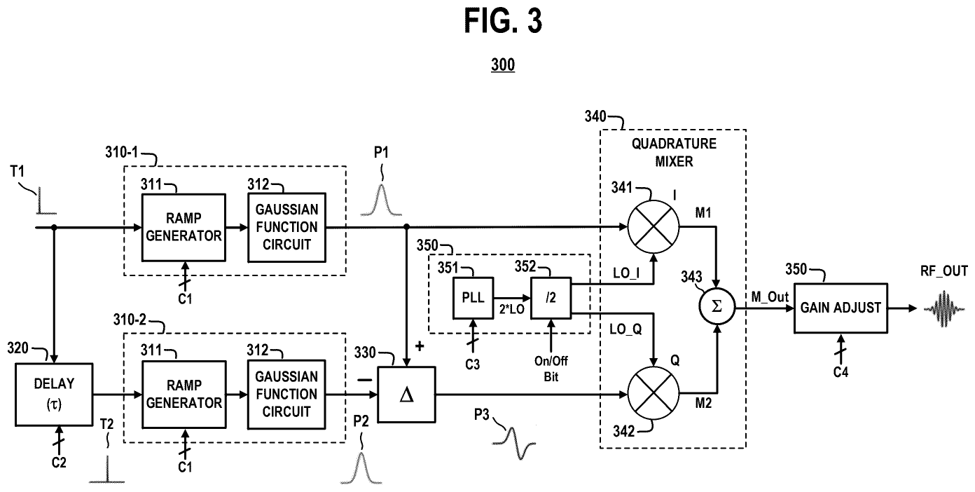

FIG. 3 schematically illustrates an analog RF pulse generator, according to another exemplary embodiment of the disclosure. In particular, FIG. 3 schematically illustrates an analog RF pulse generator 300 that is configured to generate an RF output signal, RF_OUT, which comprises a Gaussian-shaped RF control pulse with DRAG compensation, according to another exemplary embodiment of the disclosure. The analog RF pulse generator 300 comprises a first analog Gaussian pulse generator 310-1, a second analog Gaussian pulse generator 310-2, a delay circuit 320, a signal combiner 330, a quadrature mixer 340, a quadrature LO generator 350, and a gain adjust circuit 360. The first and second analog Gaussian pulse generators 310-1 and 310-2 comprise nomically identical circuit architectures, where the first and second analog Gaussian pulse generators 310-1 and 310-2 each comprise a respective ramp signal generator 311 and a respective Gaussian function circuit 312. The quadrature LO generator 350 comprises a PLL circuit 352, and a quadrature frequency divider 352. The quadrature mixer 340 comprises a first mixer 341 (or I-mixer), a second mixer 342 (or Q-mixer), and a signal combiner 343.

In some embodiments, the first and second analog Gaussian pulse generators 310-1 and 310-2, the delay circuit 320, the signal combiner 330, the quadrature mixer 340, the quadrature LO generator 350, and the gain adjust circuit 360, implement the same or similar circuit architectures and modes of operation as the corresponding circuit components of the analog RF pulse generators 100 and 200 of FIGS. 1 and 2 as discussed above, the details of which need not be repeated. However, the analog RF pulse generator 300 is configured to generate the time-delayed Gaussian pulse P2 using a different technique, as compared to the analog RF pulse generators 100 and 200 discussed above.

In particular, as schematically shown in FIG. 3, the first analog Gaussian pulse generator 310-1 is configured to generate and output a first Gaussian pulse P1 in response to a first trigger signal T1 that is directly applied to a control input of the ramp signal generator 311 of the first analog Gaussian pulse generator 310-1. However, the first trigger signal T1 is applied to the input port of the delay circuit 320, wherein the delay circuit 320 is configured to apply a specified time delay (τ) (or propagation delay) and output a second trigger signal T2 which comprises a time-delayed version of the first trigger signal T1. The second trigger signal T2 is directly applied to a control input of the ramp signal generator 311 of the second analog Gaussian pulse generator 310-2, which causes the second analog Gaussian pulse generator 310-2 to generate and output a second Gaussian pulse P2 in response to the second trigger signal T2. In this regard, due to the delayed triggering (e.g., time delay of τ) of the second analog Gaussian pulse generator 310-2, the second Gaussian pulse generator 310-2 will generate and output the second Gaussian pulse P2, wherein the second Gaussian pulse P2 (e.g., g(t+τ)) is essentially a time-delayed version of the first Gaussian pulse P1 (e.g. g(t)).

With the exemplary analog RF pulse generators 100 and 200 of FIGS. 1 and 2, the second Gaussian pulse P2 is generated by utilizing a delay circuit to delay the first Gaussian pulse P1 and generate the second Gaussian pulse P2. On the other hand, with the exemplary analog RF pulse generator 300 of FIG. 3, the delay circuit 320 is utilized to delay the first trigger signal T1 to generate the second (delayed) trigger signal T2, in which case the second (delayed) Gaussian pulse P2 is generated without having to actually delay an analog pulse of variable width (e.g., P1), which is more difficult to implement as compared to simply delaying a trigger control pulse. Indeed, in the exemplary embodiment of FIG. 3, the delay circuit 320 can be implemented as a digital delay circuit that is configured to apply a programmatically controlled time delay (τ) to the trigger pulse T1 using well known circuits and techniques.

While the analog RF pulse generator 300 of FIG. 3 generates the second (time-delayed) Gaussian pulse P2 without delaying the first Gaussian pulse P1, the analog RF pulse generator 300 generates the DRAG pulse using the same techniques as discussed above. In particular, as shown in FIG. 3, the signal combiner 330 is configured to combine the first and second Gaussian pulses P1 and P2 to generate the DRAG pulse P3, where, in some embodiments, the signal combiner 330 generates the DRAG pulse P3 as a difference between the first and second Gaussian pulses P1 and P2, e.g., P1-P2, or g(t)−g(t+τ).

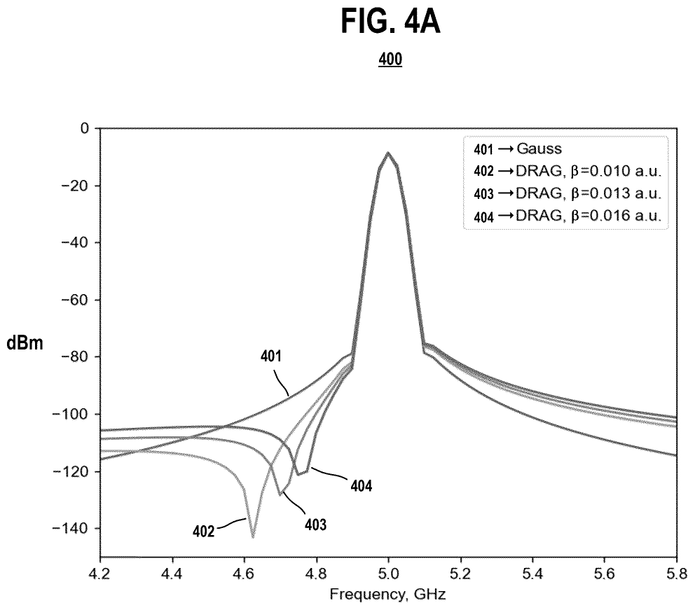

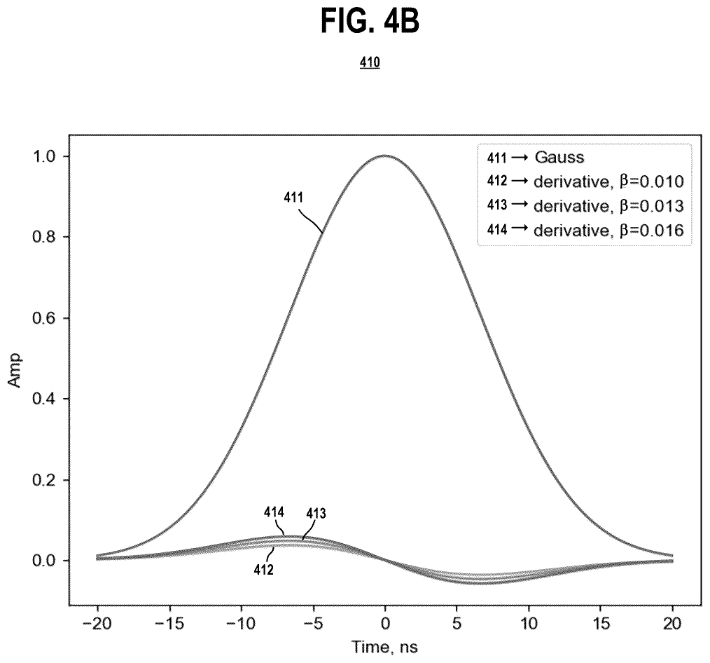

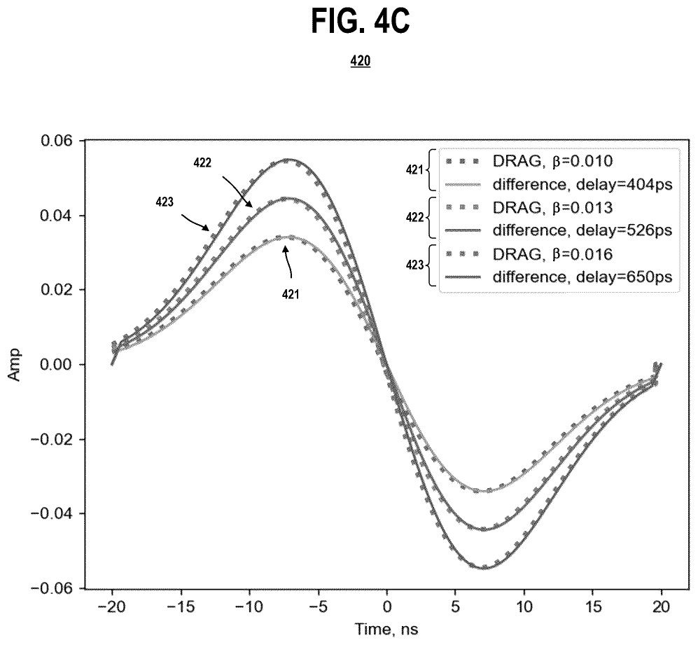

FIG. 4A depicts a frequency-domain graph of simulated RF output signals that can be generated using an analog RF pulse generator, according to an exemplary embodiment of the disclosure. In particular, FIG. 4A depicts a frequency-domain graph showing a power level (in dBm) as a function of frequency for a plurality of simulated RF output signal 401, 402, 403, and 404. The simulated RF output signal 401 represents an RF control pulse which is generated by modulating a LO signal with a frequency f_{LO}=5.0 GHz using a Gaussian pulse g(t) without DRAG compensation. In this instance, the simulated RF output signal 401 may represent a modulated RF output signal (M_OUT) generated by a quadrature mixer with no DRAG pulse applied to the IF port of a Q-mixer, wherein M_OUT=g(t)·cos (wt), where the angular frequency w=2πf_{LO}.

The simulated RF output signal 402 represents an RF control pulse which is generated by modulating the LO signal (f_{LO}=5.0 GHz) using the Gaussian pulse g(t) with DRAG compensation, where a DRAG pulse

$$( β \cdot \frac{dg ( t )}{dt} )$$

is computed by computing the derivative of the Gaussian pulse

$$( \frac{dg ( t )}{dt} )$$

and scaling the computed derivative with a value of β=0.010. In this instance, the simulated RF output signal 402 may represent a modulated RF output signal (M_OUT) generated by a quadrature mixer with the Gaussian pulse g(t) applied to an IF port of an I-mixer, and with the DRAG pulse

$$( 0.01 \cdot \frac{dg ( t )}{dt} )$$

applied to an IF port of an Q-mixer, where

$$M\_OUT = g ( t ) \cdot cos ( wt ) - sin ( wt ) \cdot ( 0.01 \cdot \frac{dg ( t )}{dt} ) ,$$

where the angular frequency w=2πf_{LO}.

Next, the simulated RF output signal 403 represents an RF control pulse which is generated by modulating the LO signal (f_{LO}=5.0 GHz) using the Gaussian pulse g(t) with DRAG compensation, where a DRAG pulse

$$( β \cdot \frac{dg ( t )}{dt} )$$

is computed by computing the derivative of the Gaussian pulse

$$( \frac{dg ( t )}{dt} )$$

and scaling the computed derivative with a value of β=0.013. In this instance, the simulated RF output signal 403 may represent a modulated RF output signal (M_OUT) generated by a quadrature mixer with the Gaussian pulse g(t) applied to an IF port of an I-mixer, and with the DRAG pulse

$$( 0.013 \cdot \frac{dg ( t )}{dt} )$$

applied to an IF port of an Q-mixer, where

$$M\_OUT = g ( t ) \cdot cos ( wt ) - sin ( wt ) \cdot ( 0.013 \cdot \frac{dg ( t )}{d t} ) ,$$

where the angular frequency w=2πf_{LO}.

Next, the simulated RF output signal 404 represents an RF control pulse which is generated by modulating the LO signal (f_{LO}=5.0 GHz) using the Gaussian pulse g(t) with DRAG compensation, where a DRAG pulse

$$( β \cdot \frac{dg ( t )}{d t} )$$

is computed by computing the derivative of the Gaussian pulse

$$( \frac{dg ( t )}{d t} )$$

and scaling the computed derivative with a value of β=0.016. In this instance, the simulated RF output signal 403 may represent a modulated RF output signal (M_OUT) generated by a quadrature mixer with the Gaussian pulse g(t) applied to an IF port of an I-mixer, and with the DRAG pulse

$$( 0.016 \cdot \frac{dg ( t )}{d t} )$$

applied to an IF port of an Q-mixer, where

$$M\_OUT = g ( t ) \cdot cos ( wt ) - sin ( wt ) \cdot ( 0.016 \cdot \frac{dg ( t )}{d t} ) ,$$

where the angular frequency w=2πf_{LO}.

FIG. 4B depicts a time-domain graph of simulated DRAG pulses that are generated by computing a derivative of a Gaussian pulse and scaling the computed derivative with different scaling parameters, according to an exemplary embodiment of the disclosure. In particular, FIG. 4B depicts a time-domain graph showing amplitude (normalized) as a function of time (in nanoseconds) for a Gaussian pulse 411 (g(t)), and a plurality of simulated DRAG pulses 412, 413, and 414 which are generated by computing a derivative of the Gaussian pulse 411 and applying different scaling factors. In particular, the simulated DRAG pulse 412

$$( β \cdot \frac{dg ( t )}{d t} )$$

is generated by computing the derivative of the Gaussian pulse

$$( \frac{dg ( t )}{d t} ) ,$$

and scaling the computed derivative with a value of β=0.010. The simulated DRAG pulse 413

$$( β \cdot \frac{dg ( t )}{d t} )$$

is generated by computing the derivative of the Gaussian pulse

$$( \frac{dg ( t )}{d t} ) ,$$

and scaling the computed derivative with a value of β=0.013. The simulated DRAG pulse 414

$$( β \cdot \frac{dg ( t )}{d t} )$$

is generated by computing the derivative of the Gaussian pulse

$$( \frac{dg ( t )}{d t} ) ,$$

and scaling the computed derivative with a value of β=0.016.

FIG. 4C depicts a time-domain graph of simulated DRAG pulses that are generated by varying a time delay between two Gaussian pulses which are combined to generate the DRAG pulses, according to an exemplary embodiment of the disclosure. In particular, FIG. 4C depicts a time-domain graph showing amplitude (normalized) as a function of time (in nanoseconds) for the exemplary simulated DRAG pulses shown in FIG. 4B which are generated by computing the derivative of the Gaussian pulse g(t), which are overlayed by simulated DRAG pulses that are generated by combining the Gaussian pulse g(t) with a time-delayed version of the Gaussian pulse g(t+τ), where the simulated DRAG pulses are computed as a difference between the Gaussian pulse and the time-delayed version of the Gaussian pulse, e.g., g(t)−g(t+τ).

In FIG. 4C, the simulated DRAG pulses which are computed as a difference between the Gaussian pulse and the time-delayed version of the Gaussian pulse, e.g., g(t)−g(t+τ) are depicted as solid-line waveforms, while the simulated DRAG pulses which are generated by computing the derivative of the Gaussian pulse g(t) are shown as dashed-line waveforms that overlay the corresponding solid-line waveforms. The exemplary simulated DRAG pulse waveforms of FIG. 4C illustrate that a DRAG pulse which is computed as a difference between a Gaussian pulse and a time-delayed version of the Gaussian pulse, e.g., g(t)−g(t+τ) is equivalent to computing a DRAG pulse by computing a derivative of the Gaussian pulse

$$\frac{dg ( t )}{d t}$$

and scaling by the derivative by a value of β, where the time delay τ is selected to achieve a given value β.

In particular, as shown in FIG. 4C, the overlayed simulated DRAG pulses 421 represent (i) the simulated DRAG pulse 412 of FIG. 4B, which is computed as

$$( 0.01 \cdot \frac{dg ( t )}{d t} ) ,$$

and (ii) a simulated DRAG pulse which is computed as a difference between the Gaussian pulse and the time-delayed version of the Gaussian pulse, e.g., g(t)−g(t+τ), where τ=404 picoseconds (ps). In this instance, the time delay τ=404 ps corresponds to a scaling value of β=0.010.

Next, the overlayed simulated DRAG pulses 422 represent (i) the simulated DRAG pulse 413 of FIG. 4B, which is computed as

$$( 0 \text{.013} \cdot \frac{dg ( t )}{d t} ) ,$$

and (ii) a simulated DRAG pulse which is computed as a difference between the Gaussian pulse and the time-delayed version of the Gaussian pulse, e.g., g(t)−g(t+τ), where τ=526 ps. In this instance, the time delay τ=526 ps corresponds to a scaling value of β=0.013.

Further, the overlayed simulated DRAG pulses 423 represent (i) the simulated DRAG pulse 414 of FIG. 4B, which is computed as

$$( 0.016 \cdot \frac{dg ( t )}{d t} ) ,$$

and (ii) simulated DRAG pulse which is computed as a difference between the Gaussian pulse and the time-delayed version of the Gaussian pulse, e.g., g(t)−g(t+τ), where τ=650 ps. In this instance, the time delay τ=650 ps corresponds to a scaling value of β=0.016.

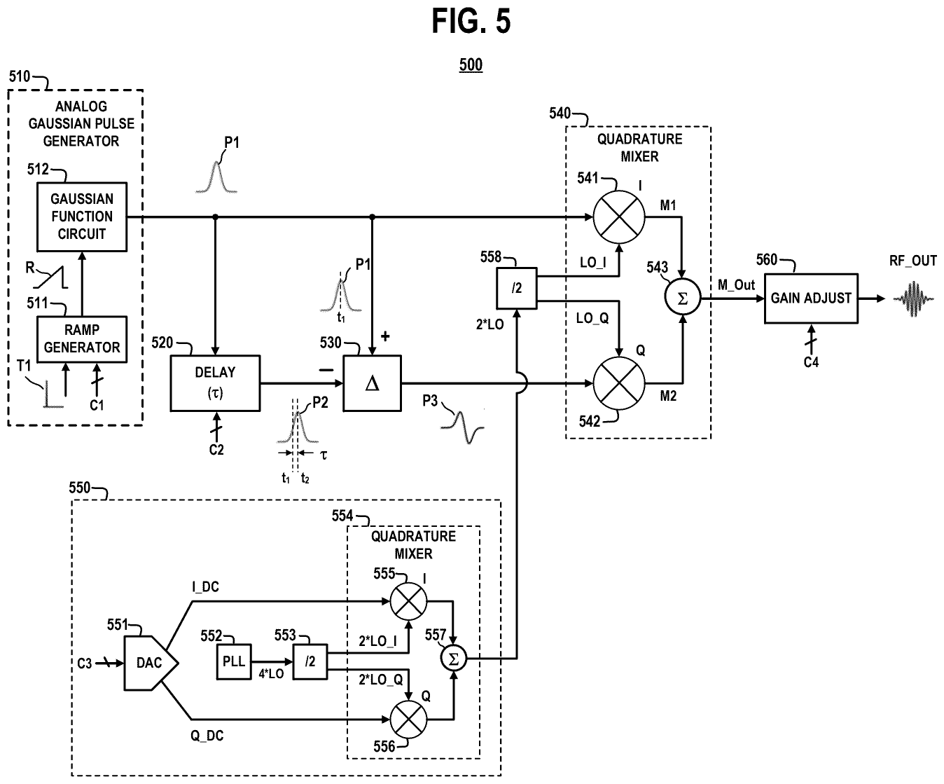

FIG. 5 schematically illustrates an analog RF pulse generator, according to another exemplary embodiment of the disclosure. In particular, FIG. 5 schematically illustrates an analog RF pulse generator 500 that is configured to generate an RF output signal, RF_OUT, which comprises a Gaussian-shaped RF control pulse with DRAG compensation, according to another exemplary embodiment of the disclosure. The analog RF pulse generator 500 comprises an analog Gaussian pulse generator 510, a delay circuit 520, a signal combiner 530, a quadrature mixer 540, a quadrature LO generator 550, and a gain adjust circuit 560. The analog Gaussian pulse generator 510 comprises a ramp signal generator 511 and a Gaussian function circuit 512. The quadrature mixer 540 comprises a first mixer 541 (or I-mixer), a second mixer 542 (or Q-mixer), and a signal combiner 543.

In some embodiments, the analog Gaussian pulse generator 510, the delay circuit 520, the signal combiner 530, the quadrature mixer 540, and the gain adjust circuit 560, implement the same or similar circuit architectures and modes of operation as the corresponding circuit components of the analog RF pulse generators 100 and 200 of FIGS. 1 and 2 discussed above, the details of which need not be repeated. The quadrature LO generator 550 is configured to generate quadrature LO signals LO_I and LO_Q, which are utilized by the quadrature mixer 540 to perform I/Q modulation and upconversion operations, as discussed above. However, the analog RF pulse generator 500 implements an exemplary architecture of the quadrature LO generator 550 to achieve LO signal generation and phase modulation in multiple stages.

As schematically illustration in FIG. 5, the quadrature LO generator 550 comprises a DAC 551, a PLL circuit 552, a first quadrature frequency divider 553, a quadrature mixer 554 (which comprises a first mixer 555 (I-mixer), a second mixer 556 (Q-mixer) and a signal combiner 557), and a second quadrature frequency divider 558. The DAC 551 is configured to generate I and Q DC components, I_DC and Q_DC, which are applied to respective IF input ports of the first mixer 555 and the second mixer 556, respectively. In this configuration, the DAC 551 is programmatically controlled by the third control signal C3 to generate the I_DC and Q_DC components to provide appropriate DC offsets to the quadrature LO signals and, thereby achieve a desired phase of the modulated output signal M_OUT which is generated by the quadrature mixer 540.

The PLL circuit 552 is configured to the generate an LO signal which is 4× the target LO frequency (e.g., 4X the transition frequency f₀₁ of a qubit that is driven by the RF_OUT signal generated by the analog RF signal generator 500). For example, assuming the transition frequency f₀₁ of the qubit is 5.0 GHz, the PLL circuit 552 is configured to generate an LO signal with a frequency of 20.0 GHz. The first quadrature frequency divider 553 is configured to divide the 4*LO signal, which is generated and output from the PLL circuit 252, into quadrature LO signals, 2*LO_I and 2*LO_Q, each having a frequency which is one-half the frequency (e.g., 10.0 GHz) of the 4*LO signal that is output from the PLL circuit 552.

The quadrature mixer 554 is configured to perform I/Q amplitude modulation in which the I_DC and Q_DC components serve as modulating signals that modulate the signals 2*LO_I and 2*LO_Q. In particular, in the exemplary configuration of FIG. 5, the first mixer 555 performs a mixing operation in which the I_DC component amplitude modulates the 2*LO_I signal, and the second mixer 556 performs a mixing operation in which the Q_DC component amplitude modulates the 2*LO_Q signal. The modulated signals that are output of the first and second mixers 555 and 556 are combined via the signal combiner 557 to generate a phase-modulated local oscillator signal 2*LO having a desired phase-shift corresponding the phase-shift indicated by the third control signal C3.

The phase-modulated local oscillator signal 2*LO is applied to an input port of the second quadrature frequency divider 558. The second quadrature frequency divider 558 is configured to divide the phase-modulated 2*LO signal, which is generated and output from the quadrature mixer 554, into quadrature LO signals, LO_I and LO_Q, each having a frequency which is one-half the frequency (e.g., 5.0 GHz) of the phase-modulated 2*LO signal. The quadrature LO signals, LO_I and LO_Q are then mixed with the Gaussian pulse P1 and the DRAG pulse P3, respectively, by the quadrature mixer 540 to perform I/Q modulation and thereby generate the modulated output signal M_OUT with the desired phase.

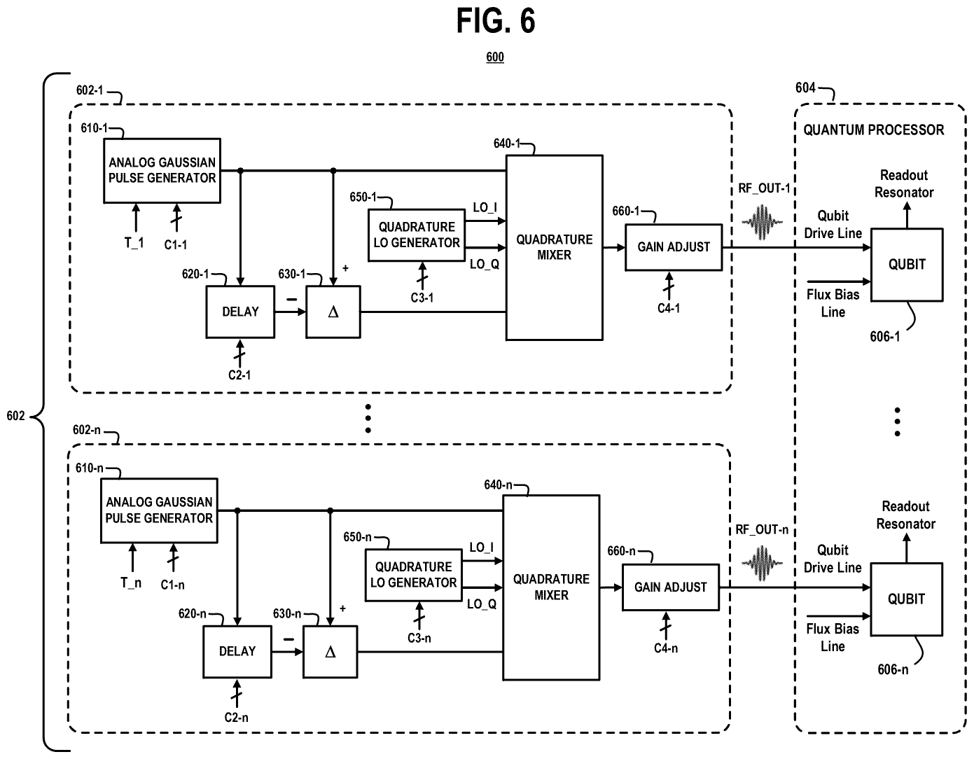

FIG. 6 schematically illustrates a quantum computing system which a implements multi-channel analog RF pulse generator to generate RF control pulses for controlling qubits of a quantum processor, according to an exemplary embodiment of the disclosure. For example, FIG. 6 schematically illustrates a quantum computing system 600 which a multi-channel analog RF pulse generator 602 and a quantum processor 604. The quantum processor 604 comprises a plurality (n) of superconducting qubits 606-1, . . . , 606-n. The superconducting qubits 606-1, . . . , 606-n may comprise superconducting transmon qubits, superconducting fluxonium qubits, superconducting multi-mode qubits, and other types, or combinations of different types, of superconducting qubits, which are suitable for a given application. Further, in some embodiments, the quantum processor 604 comprises coupler circuits (e.g., passive coupler circuits and/or active coupler circuits), wherein a given coupler circuit is configured to couple a pair of superconducting qubits to implement entanglement gate operations (e.g., two-qubit gate operations).

The quantum processor 604 further comprises a plurality of control lines (e.g., transmission line resonators) including, but not limited to, qubit drive lines, flux bias lines, qubit readout resonators, and active coupler drive lines, etc. In some embodiments, the qubit drive lines are coupled (e.g., capacitively coupled) to respective ones of the superconducting qubits 606-1, . . . 606-n. The qubit drive lines are configured to apply respective control pulses RF_OUT-1, . . . RF_OUT-n (which are generated by the multi-channel analog RF pulse generator 602) to the respective superconducting qubits 606-1, . . . , 606-n to independently change the states of the respective superconducting qubits (e.g., single-qubit gate operations e.g., change the state of a given superconducting qubit to be in, e.g., a ground state |0 [symbol] , an excited state |1 [symbol] or a superposition state. In some embodiments, the superconducting qubits 606-1, . . . , 606-n are configured to have different operating frequencies (transition frequencies) so that the transition frequencies of neighboring qubits are detuned.

The qubit readout resonators are coupled to respective ones of the superconducting qubits 606-1, . . . , 606-n to read the states of the superconducting qubits using known techniques (e.g., dispersive readout). In embodiments where the superconducting qubits 606-1, . . . , 606-n comprise frequency-tunable qubits (e.g., flux-tunable transmon qubits or fluxonium qubits, etc.), the flux bias control lines would be coupled (e.g., inductively coupled) to respective superconducting qubits to apply flux bias control signals to tuning structures of the superconducting qubits to tune the operating frequencies of the tunable qubits, as needed for a given application. In addition, for active coupler circuits, coupler drive lines would be coupled (e.g., capacitively coupled) to respective coupler circuits, wherein each coupler circuit would have an operating frequency or transition frequency. A given coupler circuit would be driven by a control pulse generated by other channels of the multi-channel analog RF pulse generator 602, or some other pulse signal generator, to enable exchange coupling between superconducting qubits that are coupled through the given coupler circuit and implement a two-qubit gate operation.

As shown in FIG. 6, the multi-channel analog RF pulse generator 602 comprises a plurality of analog RF pulse generator channels 602-1, . . . , 602-n which are configured to generate respective RF control pulses RF, RF_OUT-1, . . . , RF_OUT-n, which are applied on respective qubit drive lines to control respective ones of the superconducting qubits 606-1, . . . , 606-n. Although not specifically shown in FIG. 6, in some embodiments, the multi-channel analog RF pulse generator 602 could include additional channels to generate control signals that are applied to coupler drive lines to control active coupler devices of the quantum processor 604.

In some embodiments, the analog RF pulse generator channels 602-1, . . . , 602-n are nominally identical and implement the exemplary analog RF pulse generator 100 (of FIG. 1) that is configured to generate an RF output signal which comprises a Gaussian-shaped RF control pulse with DRAG compensation. In particular, as shown in FIG. 6, the analog RF pulse generator channels 602-1, . . . , 602-n comprise respective analog Gaussian pulse generators 610-1, . . . , 610-n, respective delay circuits 620-1, . . . , 620-n, respective signal combiners 630-1, . . . , 630-n, respective quadrature mixers 640-1, . . . , 640-n, respective quadrature LO generators 650-1, . . . , 650-n, and respective gain adjust circuits 660-1, . . . , 660-n, which implement the same or similar circuit architectures and modes of operation as the corresponding circuit components discussed above the details of which will not be repeated. It is to be noted that while the analog RF pulse generator channels 602-1, . . . , 602-n are shown as being implement using the exemplary analog RF pulse generator architecture of FIG. 1, in other alternative embodiments, the analog RF pulse generator channels 602-1, . . . , 602-n can be implemented using any one of the exemplary architectures of the analog RF pulse generators 200, 300, or 500 as shown and discussed above in conjunction with FIGS. 2, 3, and 5.

The quadrature LO generators 650-1, . . . , 650-n of the respective analog RF pulse generator channels 602-1, . . . , 602-n are configured to generate respective LO signals with respective target frequencies that correspond to respective transition frequencies f₀₁ of the respective superconducting qubits 606-1, . . . , 606-n which driven by the respective analog RF pulse generator channels 602-1, . . . , 602-n. In addition, each analog RF pulse generator channel 602-1, . . . , 602-n is controlled by corresponding set of control signals to adjust the parameters of the RF control pulses RF_OUT-1, . . . , RF_OUT-n that are generated by the respective analog RF pulse generator channels 602-1, . . . , 602-n. For example, as shown in FIG. 6, the analog RF pulse generator channel 602-1 is controlled by a set of control signals T-1, C1-1, C2-1, C3-1, and C4-1, and the analog RF pulse generator channel 602-n is controlled by a set of control signals T-n C1-n, C2-n, C3-n, and C4-n. In some embodiments, the control signals are generated by software running on a computing platform that controls operation of the quantum computing system 600.

As noted above, the control signals T-1, . . . , T-n comprise trigger pulses that are applied to the respective analog Gaussian pulse generators 610-1, . . . , 610-n to trigger the generation of Gaussian pulses, which, in turn, result in the generation of respective RF output pulses RF_OUT-1, . . . , RF_OUT-n by the respective analog RF pulse generator channels 602-1, . . . , 602-n. The first control signals C1-1, . . . , C1-n comprise digital control signals that are applied the respective analog Gaussian pulse generators 610-1, . . . , 610-n which, as noted above, programmatically set the respective durations (pulse widths) of the respective RF output pulses RF_OUT-1, . . . , RF_OUT-n that are generated and output from the respective analog RF pulse generator channels 602-1, . . . , 602-n. In addition, the second control signals C2-1, . . . , C2-n comprise digital control signals that are applied the respective delay circuits 620-1, . . . , 620-n to programmatically set respective time delays (τ) which, in turn, programmatically set the respective amounts of DRAG compensation which is applied to the respective RF output pulses RF_OUT-1, . . . , RF_OUT-n that are generated and output from the respective analog RF pulse generator channels 602-1, . . . , 602-n.

Further, the third control signals C3-1, . . . , C3-n comprise digital control signals that are applied the respective quadrature LO generators 650-1, . . . , 650-n which, as noted above, programmatically set respective phase-shifts of the respective RF output pulses RF_OUT-1, . . . , RF_OUT-n that are generated and output from the respective analog RF pulse generator channels 602-1, . . . , 602-n. Moreover, the fourth control signals C4-1, . . . , C4-n comprise digital control signals that are applied the respective gain adjust circuits 660-1, . . . , 660-n which, as noted above, programmatically set respective amplitudes of the respective RF output pulses RF_OUT-1, . . . , RF_OUT-n that are generated and output from the respective analog RF pulse generator channels 602-1, . . . , 602-n.

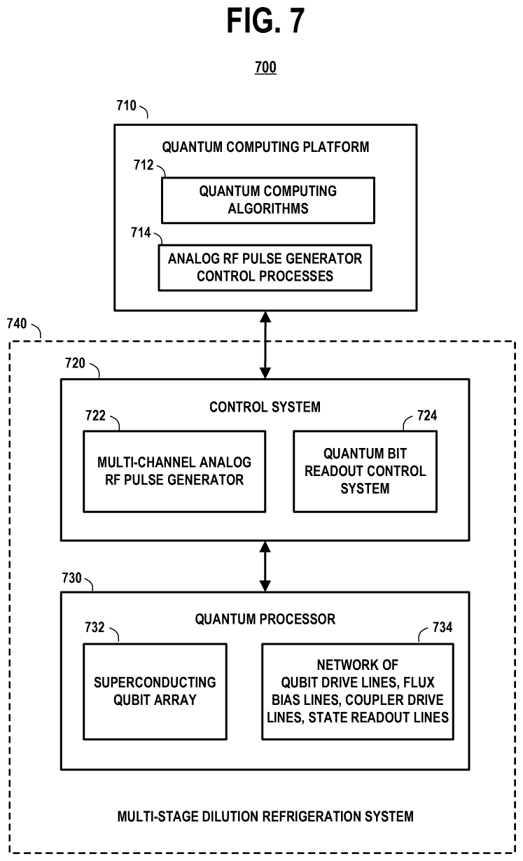

FIG. 7 schematically illustrates a quantum computing system, according to another exemplary embodiment of the disclosure. In particular, FIG. 7 schematically illustrates a quantum computing system 700 which comprises a quantum computing platform 710, a control system 720, and a quantum processor 730. In some embodiments, the quantum computing platform 710 implements software programs such as quantum computing algorithms 712 to perform quantum computing or quantum information process, and control processes 714 for controlling and configuring a multi-channel analog RF pulse generator, etc. etc.

Furthermore, the quantum computing platform 710 executes calibration procedures that are periodically performed on a quantum system such as a quantum processor to calibrate various quantum elements such as readout resonators, data qubits, and coupler circuitry, etc., to enable high-fidelity gate operations (e.g., single-qubit gate operations and entanglement gate operations). For example, various types of in-situ calibration procedures are periodically performed to, e.g., determine the resonant frequencies of readout resonators, determine the transition frequencies of qubits, determine coherence times (T₁) of the qubits (where the coherence time T₁ of a given qubit denotes the time it takes for the qubit state to decay from the excited state to the ground state), determine transverse relaxation times (T₂) of the qubits (or dephasing time), calibrate control pulses that are applied to qubits to perform single-qubit gate operations, calibrate control pulses that are applied to active coupler circuits to perform entanglement gate operations, etc. The calibration procedures result in determining various control parameters that are maintained in a calibration database and periodically updated on the order of seconds, minutes, hours, days, etc., as needed, depending on the type of quantum element and the operating characteristics of the quantum computing system, and other factors as is understood by those of ordinary skill in the art.

In some embodiments, the control system 720 comprises a multi-channel analog RF pulse generator 722, and a quantum bit readout control system 724, wherein 6 schematically illustrates an exemplary embodiment of a multi-channel analog RF pulse generator system 602 which can used to implement the multi-channel analog RF pulse generator 722 of the control system 720. The quantum processor 730 comprises one or more quantum processor chips comprising a superconducting qubit array 732 and a network 734 of qubit drive lines, coupler drive lines, and qubit readout resonator lines, and other circuit QED components that may be needed for a given application or quantum system configuration.

In some embodiments, the control system 720 and the quantum processor 730 are disposed in a dilution refrigeration system 740 which can generate cryogenic temperatures that are sufficient to operate components of the control system 720 for quantum computing applications. For example, the quantum processor 730 may need to be cooled down to near-absolute zero, e.g., 10-15 millikelvin (mK), to allow the superconducting qubits to exhibit quantum behaviors. In some embodiments, the dilution refrigeration system 740 comprises a multi-stage dilution refrigerator where the components of the control system 720 can be maintained at different cryogenic temperatures, as needed. For example, while the quantum processor 730 may need to be cooled down to, e.g., 10-15 mK, the circuit components of the control system 720 may be operated at cryogenic temperatures greater than 10-15 mK (e.g., cryogenic temperatures in a range of 3K-4K), depending on the configuration of the quantum computing system.

In some embodiments, the superconducting qubit array 732 comprises a plurality of superconducting transmon qubits and superconducting tunable coupler qubits, in which each pair of superconducting qubits is connected by a respective superconducting qubit coupler, using techniques as discussed herein. The network 734 of qubit drive lines, flux bias lines, coupler drive lines, qubit readout resonators, and readout lines, etc., are configured to apply microwave control signals to superconducting qubits and coupler circuitry in the superconducting qubit array 732 to perform various types of gate operations, e.g., single-gate operations, entanglement gate operations, etc., as well as read the quantum states of the superconducting qubits. The network 734 of qubit drive lines, flux bias lines, coupler drive lines, and qubit readout resonators, and readout lines, etc., is coupled to the control system 720 through a suitable hardware input/output (I/O) interface, which couples I/O signals between the control system 720 and the quantum processor 730. For example, the hardware I/O interface may comprise various types of hardware and components, such as RF cables, wiring, RF elements, optical fibers, heat exchanges, filters, amplifiers, isolators, etc.

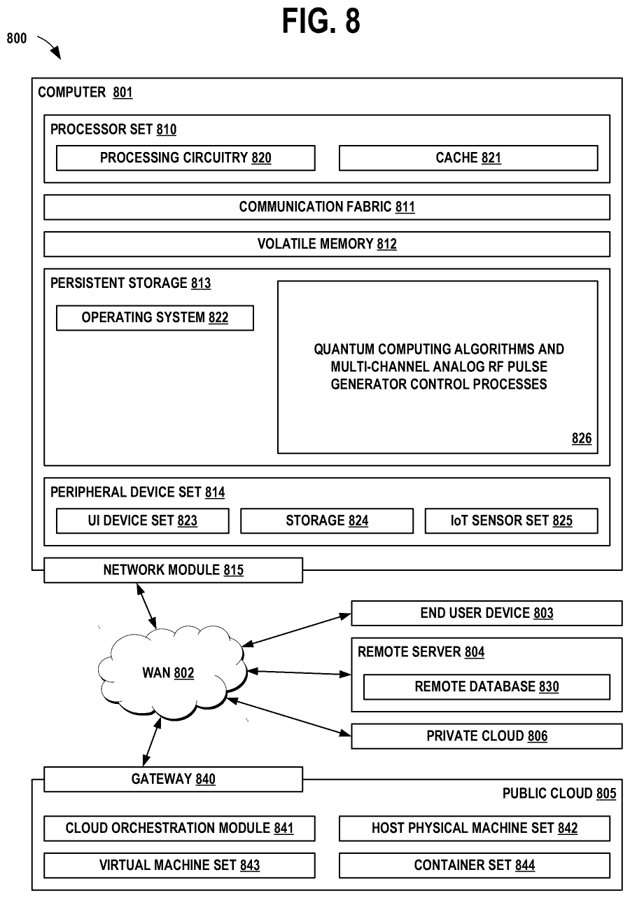

The quantum computing platform 710 comprises a software and hardware platform which comprises various software layers that are configured to perform various functions, including, but not limited to, generating and implementing various quantum applications using suitable quantum programming languages, configuring and implementing various quantum gate operations, compiling quantum programs into a quantum assembly language, implementing and utilizing a suitable quantum instruction set architecture (ISA), performing calibration operations to calibrate the quantum circuit elements and gate operations, etc. In addition, the quantum computing platform 710 comprises a hardware architecture of processors, memory, etc., which is configured to control the execution of quantum applications, and interface with the control system 720 to (i) generate digital control signals that are converted to analog microwave control signals by the control system 720, to control operations of the quantum processor 730 when executing a given quantum application, and (ii) to obtain and process digital signals received from the control system 720, which represent the processing results generated by the quantum processor 730 when executing various gate operations for a given quantum application. In some exemplary embodiments, the quantum computing platform 710 of the quantum computing system 700 may be implemented using any suitable computing system architecture (e.g., as shown in FIG. 8) which is configured to implement methods to support quantum computing operations by executing computer readable program instructions that are embodied on a computer program product which includes a computer readable storage medium (or media) having such computer readable program instructions thereon for causing a processor to perform control methods as discussed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

FIG. 8 schematically illustrates an exemplary computing environment which is configured to execute program instructions for performing quantum computing operations and controlling RF pulse generators, according to an exemplary embodiment of the disclosure. The computing environment 800 schematically illustrates an exemplary embodiment of an environment for the execution of at least some of the computer code 826 involved in performing inventive methods, such as quantum computing algorithms to perform quantum computing or quantum information processing, and code to perform control processes for controlling and configuring analog RF pulse generators (such as shown in FIGS. 1, 2, 3, and 5) or a multi-channel analog RF pulse generator (such as shown in FIG. 6), etc. In addition to block 826, computing environment 800 includes, for example, computer 801, wide area network (WAN) 802, end user device (EUD) 803, remote server 804, public cloud 805, and private cloud 806. In this embodiment, computer 801 includes processor set 810 (including processing circuitry 820 and cache 821), communication fabric 811, volatile memory 812, persistent storage 813 (including operating system 822 and block 826, as identified above), peripheral device set 814 (including user interface (UI), device set 823, storage 824, and Internet of Things (IoT) sensor set 825), and network module 815. Remote server 804 includes remote database 830. Public cloud 805 includes gateway 840, cloud orchestration module 841, host physical machine set 842, virtual machine set 843, and container set 844.

Computer 801 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 830. As is well understood in the art of computer technology, and depending upon the technology, performance of a computer-implemented method may be distributed among multiple computers and/or between multiple locations. On the other hand, in this presentation of computing environment 800, detailed discussion is focused on a single computer, specifically computer 801, to keep the presentation as simple as possible. Computer 801 may be located in a cloud, even though it is not shown in a cloud in FIG. 8. On the other hand, computer 801 is not required to be in a cloud except to any extent as may be affirmatively indicated.

Processor set 810 includes one, or more, computer processors of any type now known or to be developed in the future. Processing circuitry 820 may be distributed over multiple packages, for example, multiple, coordinated integrated circuit chips. Processing circuitry 820 may implement multiple processor threads and/or multiple processor cores. Cache 821 is memory that is located in the processor chip package(s) and is typically used for data or code that should be available for rapid access by the threads or cores running on processor set 810. Cache memories are typically organized into multiple levels depending upon relative proximity to the processing circuitry. Alternatively, some, or all, of the cache for the processor set may be located “off chip.” In some computing environments, processor set 810 may be designed for working with qubits and performing quantum computing.

Computer readable program instructions are typically loaded onto computer 801 to cause a series of operational steps to be performed by processor set 810 of computer 801 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 821 and the other storage media discussed below. The program instructions, and associated data, are accessed by processor set 810 to control and direct performance of the inventive methods. In computing environment 800, at least some of the instructions for performing the inventive methods may be stored in block 826 in persistent storage 813.

Communication fabric 811 is the signal conduction paths that allow the various components of computer 801 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 812 is any type of volatile memory now known or to be developed in the future. Examples include dynamic type random access memory (RAM) or static type RAM. Typically, the volatile memory is characterized by random access, but this is not required unless affirmatively indicated. In computer 801, the volatile memory 812 is located in a single package and is internal to computer 801, but, alternatively or additionally, the volatile memory may be distributed over multiple packages and/or located externally with respect to computer 801.

Persistent storage 813 is any form of non-volatile storage for computers that is now known or to be developed in the future. The non-volatility of this storage means that the stored data is maintained regardless of whether power is being supplied to computer 801 and/or directly to persistent storage 813. Persistent storage 813 may be a read only memory (ROM), but typically at least a portion of the persistent storage allows writing of data, deletion of data and re-writing of data. Some familiar forms of persistent storage include magnetic disks and solid-state storage devices. Operating system 822 may take several forms, such as various known proprietary operating systems or open-source Portable Operating System Interface type operating systems that employ a kernel. The code included in block 826 typically includes at least some of the computer code involved in performing the inventive methods.

Peripheral device set 814 includes the set of peripheral devices of computer 801. Data communication connections between the peripheral devices and the other components of computer 801 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 823 may include components such as a display screen, speaker, microphone, wearable devices (such as goggles and smart watches), keyboard, mouse, printer, touchpad, game controllers, and haptic devices. Storage 824 is external storage, such as an external hard drive, or insertable storage, such as an SD card. Storage 824 may be persistent and/or volatile. In some embodiments, storage 824 may take the form of a quantum computing storage device for storing data in the form of qubits. In embodiments where computer 801 is required to have a large amount of storage (for example, where computer 801 locally stores and manages a large database) then this storage may be provided by peripheral storage devices designed for storing very large amounts of data, such as a storage area network (SAN) that is shared by multiple, geographically distributed computers. IoT sensor set 825 is made up of sensors that can be used in Internet of Things applications. For example, one sensor may be a thermometer and another sensor may be a motion detector.

Network module 815 is the collection of computer software, hardware, and firmware that allows computer 801 to communicate with other computers through WAN 802. Network module 815 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 815 are performed on the same physical hardware device. In other embodiments (for example, embodiments that utilize software-defined networking (SDN)), the control functions and the forwarding functions of network module 815 are performed on physically separate devices, such that the control functions manage several different network hardware devices. Computer readable program instructions for performing the inventive methods can typically be downloaded to computer 801 from an external computer or external storage device through a network adapter card or network interface included in network module 815.

WAN 802 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 803 is any computer system that is used and controlled by an end user (for example, a customer of an enterprise that operates computer 801), and may take any of the forms discussed above in connection with computer 801. EUD 803 typically receives helpful and useful data from the operations of computer 801. For example, in a hypothetical case where computer 801 is designed to provide a recommendation to an end user, this recommendation would typically be communicated from network module 815 of computer 801 through WAN 802 to EUD 803. In this way, EUD 803 can display, or otherwise present, the recommendation to an end user. In some embodiments, EUD 803 may be a client device, such as thin client, heavy client, mainframe computer, desktop computer and so on.

Remote server 804 is any computer system that serves at least some data and/or functionality to computer 801. Remote server 804 may be controlled and used by the same entity that operates computer 801. Remote server 804 represents the machine(s) that collect and store helpful and useful data for use by other computers, such as computer 801. For example, in a hypothetical case where computer 801 is designed and programmed to provide a recommendation based on historical data, then this historical data may be provided to computer 801 from remote database 830 of remote server 804.

Public cloud 805 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 805 is performed by the computer hardware and/or software of cloud orchestration module 841. The computing resources provided by public cloud 805 are typically implemented by virtual computing environments that run on various computers making up the computers of host physical machine set 842, which is the universe of physical computers in and/or available to public cloud 805. The virtual computing environments (VCEs) typically take the form of virtual machines from virtual machine set 843 and/or containers from container set 844. It is understood that these VCEs may be stored as images and may be transferred among and between the various physical machine hosts, either as images or after instantiation of the VCE. Cloud orchestration module 841 manages the transfer and storage of images, deploys new instantiations of VCEs and manages active instantiations of VCE deployments. Gateway 840 is the collection of computer software, hardware, and firmware that allows public cloud 805 to communicate through WAN 802.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 806 is similar to public cloud 805, except that the computing resources are only available for use by a single enterprise. While private cloud 806 is depicted as being in communication with WAN 802, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 805 and private cloud 806 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
a radio frequency signal generator which comprises:
a first signal path which is configured to generate an analog pulse;
a second signal path which is configured to generate a delayed analog pulse;
a signal combiner which is configured to combine the analog pulse and the delayed analog pulse to generate an analog compensation pulse; and
a quadrature mixer which is configured to utilize the analog pulse and the analog compensation pulse to modulate quadrature local oscillator signals and generate a radio frequency control signal which comprises a frequency that corresponds to a frequency of the quadrature local oscillator signals, and a pulse shape which comprises a shape of the analog pulse modified by a shape of the analog compensation pulse.

2. The device of claim 1, wherein:
the analog pulse comprises a Gaussian pulse;
the analog compensation pulse comprises a derivative removal by adiabatic gate (DRAG) pulse;
the analog compensation pulse comprises a pulse shape that corresponds to a derivative of the Gaussian pulse; and
a magnitude of the derivative corresponds to an amount of time delay between the analog pulse and the delayed analog pulse.

3. The device of claim 1, wherein:
the first signal path comprises an analog pulse generator circuit which is configured to generate the analog pulse in response to a control trigger pulse; and
the analog pulse generator circuit is responsive to a first digital control signal to generate the analog pulse having a pulse width which is specified by the first digital control signal.

4. The device of claim 3, wherein:
the analog pulse generator circuit comprises a ramp signal generator, and an analog pulse generator;
the ramp signal generator is configured to generate a linear ramp signal in response to the control trigger pulse, the linear ramp signal having a slope which is specified by the first digital control signal; and
the analog pulse generator is configured to convert the linear ramp signal to an analog pulse having a Gaussian shape, and a pulse width that is based on the slope of the linear ramp signal.

5. The device of claim 4, wherein:
the second signal path comprises a delay circuit which is configured to receive the analog pulse generated by the analog pulse generator circuit, and apply a time delay to the analog pulse to generate the delayed analog pulse; and
the delay circuit is responsive to a second control signal which specifies an amount of time delay to apply to the analog pulse.

6. The device of claim 1, wherein:
the first signal path comprises a first analog pulse generator circuit which is configured to generate a first analog pulse in response to a control trigger pulse, and which is responsive to a first digital control signal to generate the first analog pulse having a pulse width that is specified by the first digital control signal;
the second signal path comprises a delay circuit, and a second analog pulse generator circuit;
the delay circuit is configured to receive the control trigger pulse concurrently with the first analog pulse generator circuit, and apply a time delay to the control trigger pulse to generate a delayed control trigger pulse;
the second analog pulse generator circuit is configured to generate a second analog pulse in response to the delayed control trigger pulse, and is responsive to the first digital control signal to generate the second analog pulse having as same pulse width as the first analog pulse, which is specified by the first digital control signal; and
the signal combiner generates the analog compensation pulse by combing the first analog pulse and the second analog pulse, the second analog pulse being time-delayed relative to the first analog pulse based on the time delay applied to the control trigger pulse by the delay circuit.

7. The device of claim 1, wherein the radio frequency signal generator further comprises a quadrature local oscillator generator which is configured to generate the quadrature local oscillator signals including an in-phase local oscillator signal and a quadrature-phase local oscillator signal, wherein the quadrature local oscillator generator is responsive to a third digital control signal to cause the quadrature local oscillator signals to have a phase shift which is specified by the third digital control signal.

8. The device of claim 7, wherein the quadrature mixer comprises:
a first mixer comprising a first input port to receive the analog pulse, a second input port to receive the in-phase local oscillator signal, and an output port to output a first modulated signal comprising the in-phase local oscillator signal amplitude modulated by the analog pulse; and
a second mixer comprising a first input port to receive the analog compensation pulse, a second input port to receive the quadrature-phase local oscillator signal, and an output port to output a second modulated signal comprising the quadrature-phase local oscillator signal amplitude modulated by the analog compensation pulse;
wherein the quadrature mixer is configured to combine the first modulated signal and the second modulated signal to generate the radio frequency control signal.

9. The device of claim 7, wherein the quadrature local oscillator generator comprises:
a phase-lock loop circuit which is configured to generate a local oscillator signal having a frequency which is double the frequency of the quadrature local oscillator signals, and which is responsive to the third digital control signal to apply the phase shift to the local oscillator signal that is output from the phase-lock loop circuit; and
a quadrature frequency divider circuit which is configured to divide the local oscillator signal that is output from the phase-lock loop circuit to generate the in-phase local oscillator signal and the quadrature-phase local oscillator signal.

10. The device of claim 1, wherein the radio frequency signal generator further comprises a gain adjust circuit coupled to an output of the quadrature mixer, wherein the gain adjust circuit is configured to adjust an amplitude of the radio frequency control signal in response to a fourth digital control signal applied to the gain adjust circuit.

11. A system, comprising:
a quantum processor comprising at least one quantum bit;
a radio frequency signal generator system comprising at least one radio frequency signal generator channel that is configured to generate a radio frequency control signal to control the at least one quantum bit, wherein the at least one radio frequency signal generator channel comprises:
a first signal path which is configured to generate an analog pulse;
a second signal path which is configured to generate a delayed analog pulse;
a signal combiner which is configured to combine the analog pulse and the delayed analog pulse to generate an analog compensation pulse; and
a quadrature mixer which is configured to utilize the analog pulse and the analog compensation pulse to modulate quadrature local oscillator signals and generate the radio frequency control signal to control the at least one quantum bit, wherein the radio frequency control signal comprises a frequency which corresponds to a frequency of the quadrature local oscillator signals, and a pulse shape which comprises a shape of the analog pulse modified by a shape of the analog compensation pulse.

12. The system of claim 11, wherein:
the analog pulse comprises a Gaussian pulse;
the analog compensation pulse comprises a derivative removal by adiabatic gate (DRAG) pulse;
the analog compensation pulse comprises a pulse shape that corresponds to a derivative of the Gaussian pulse; and
a magnitude of the derivative corresponds to an amount of time delay between the analog pulse and the delayed analog pulse.

13. The system of claim 11, wherein:
the first signal path comprises an analog pulse generator circuit which is configured to generate the analog pulse in response to a control trigger pulse; and
the analog pulse generator circuit is responsive to a first digital control signal to generate the analog pulse having a pulse width which is specified by the first digital control signal.

14. The system of claim 13, wherein:
the analog pulse generator circuit comprises a ramp signal generator, and an analog pulse generator;
the ramp signal generator is configured to generate a linear ramp signal in response to the control trigger pulse, the linear ramp signal having a slope which is specified by the first digital control signal; and
the analog pulse generator is configured to convert the linear ramp signal to an analog pulse having a Gaussian shape, and a pulse width that is based on the slope of the linear ramp signal.

15. The system of claim 13, wherein:
the second signal path comprises a delay circuit which is configured to receive the analog pulse generated by the analog pulse generator circuit, and apply a time delay to the analog pulse to generate the delayed analog pulse; and
the delay circuit is responsive to a second control signal which specifies an amount of time delay to apply to the analog pulse.

16. The system of claim 11, wherein:
the first signal path comprises a first analog pulse generator circuit which is configured to generate a first analog pulse in response to a control trigger pulse, and which is responsive to a first digital control signal to generate the first analog pulse having a pulse width that is specified by the first digital control signal;
the second signal path comprises a delay circuit, and a second analog pulse generator circuit;
the delay circuit is configured to receive the control trigger pulse concurrently with the first analog pulse generator circuit, and apply a time delay to the control trigger pulse to generate a delayed control trigger pulse;
the second analog pulse generator circuit is configured to generate a second analog pulse in response to the delayed control trigger pulse, and is responsive to the first digital control signal to generate the second analog pulse having as same pulse width as the first analog pulse, which is specified by the first digital control signal; and
the signal combiner generates the analog compensation pulse by combing the first analog pulse and the second analog pulse, the second analog pulse being time-delayed relative to the first analog pulse based on the time delay applied to the control trigger pulse by the delay circuit.

17. The system of claim 11, wherein the at least one radio frequency signal generator channel further comprises a gain adjust circuit coupled to an output of the quadrature mixer, wherein the gain adjust circuit is configured to adjust an amplitude of the radio frequency control signal in response to a fourth digital control signal applied to the gain adjust circuit.

18. The system of claim 11, further comprising:
a quadrature local oscillator generator which is configured to generate the quadrature local oscillator signals including an in-phase local oscillator signal and a quadrature-phase local oscillator signal, wherein the quadrature local oscillator generator is responsive to a third digital control signal to cause the quadrature local oscillator signals to have a phase shift which is specified by the third digital control signal;
wherein the quadrature local oscillator generator comprises:
a phase-lock loop circuit which is configured to generate a local oscillator signal having a frequency which is double the frequency of the quadrature local oscillator signals, and which is responsive to the third digital control signal to apply the phase shift to the local oscillator signal that is output from the phase-lock loop circuit; and
a quadrature frequency divider circuit which is configured to divide the local oscillator signal that is output from the phase-lock loop circuit to generate the in-phase local oscillator signal and a quadrature-phase local oscillator signal;
wherein the quadrature mixer comprises:
a first mixer comprising a first input port to receive the analog pulse, a second input port to receive the in-phase local oscillator signal, and an output port to output a first modulated signal comprising the in-phase local oscillator signal amplitude modulated by the analog pulse; and
a second mixer comprising a first input port to receive the analog compensation pulse, a second input port to receive the quadrature-phase local oscillator signal, and an output port to output a second modulated signal comprising the quadrature-phase local oscillator signal amplitude modulated by the analog compensation pulse;
wherein the quadrature mixer is configured to combine the first modulated signal and the second modulated signal to generate the radio frequency control signal.

19. A system, comprising:
a radio frequency signal generator comprising analog circuitry that is configured to:
generate an analog pulse;
generate a delayed analog pulse;
combine the analog pulse and the delayed analog pulse to generate an analog compensation pulse; and
amplitude modulate quadrature local oscillator signals using the analog pulse and the analog compensation pulse to generate a radio frequency control signal which comprises a frequency that corresponds to a frequency of the quadrature local oscillator signals, and a pulse shape which comprises a shape of the analog pulse modified by a shape of the analog compensation pulse; and
a control system that is configured to generate digital control signals to control the analog circuitry to adjust parameters of the radio frequency control signal by controllably adjusting: a pulse width of the analog pulse; a time delay between the analog pulse and the delayed analog pulse; a phase-shift of the quadrature local oscillator signals; and an amplitude of the radio frequency control signal.

20. The system of claim 19, wherein:
the analog pulse comprises a Gaussian pulse;
the analog compensation pulse comprises a derivative removal by adiabatic gate (DRAG) pulse;
the analog compensation pulse comprises a pulse shape that corresponds to a derivative of the Gaussian pulse; and
a magnitude of the derivative corresponds to an amount of time delay between the analog pulse and the delayed analog pulse.
